(19) United States
(12) Patent Application Publication
(10) Pub. No.: US 2009/0059675 A1
(43) Pub. Date: Mar. 5, 2009

(54) Radiation hardened multi-bit sonos non-volatile memory

(76) Inventors: Joseph T. Smith, Columbia, MD (US); Dennis A. Adams, Gambrills, MD (US); Stephen J. Wrazien, Cranberry, PA (US); Michael D. Fitzpatrick, Baltimore, MD (US); Philip Smith, Ellicott City, MD (US)

Correspondence Address: ANDREWS KURTH LLP, 1350 I STREET, N.W., SUITE 1100, WASHINGTON, DC, 20005, US

(21) Appl. No.: 11/892,874

(22) Filed: Aug. 28, 2007

(51) Int. Cl. G11C 11/34; H01L 21/336; H01L 29/94

(52) U.S. Cl. 365/185.25; 257/324; 438/287; 257/E29.309; 257/E21.423

(57) ABSTRACT

In one aspect, a radiation hardened transistor includes a buried source, buried drain and a poly-silicon gate separated from the buried source and the buried drain by a buried oxide. A recessed P+ implant or a blanket P+ implant is disposed in a substrate. A portion of the recessed P+ implant or a portion of the blanket P+ implant is disposed beneath outer edges of the poly-silicon gate, in a channel separating the buried source and the buried drain.

### FIELD OF THE INVENTION

Embodiments of the invention relate to metal oxide semiconductor (MOS) non-volatile semiconductor memories. Specifically, the invention relates to non-volatile semiconductor memory, and methods for making the same, intended to operate in a radiation exposed environment.

### BACKGROUND OF THE INVENTION

Non-Volatile Semiconductor Memory (NVSM) is a class of non-volatile memory (NVM) where the stored content or information (bit) in the semiconductor memory is preserved whenever power is removed from the device. Thus, NVSM devices retain stored information even without a power source. NVSM devices are used in computers, PDAs, mobile phones, digital cameras, and other devices requiring a non-volatile memory.

NVSMs that use charge storage as the memory mechanism utilize one of two physical device structures called “floating gate” and “SONOS” (silicon-oxide-nitride-oxide-silicon). A conventional floating gate memory cell contains a control gate and an electrically isolated floating gate. The electrically isolated floating gate is located below the control gate and above a transistor channel. The electrically isolated floating gate is separated from the control gate and the transistor by oxide. The floating gate includes a conducting material, typically a poly-silicon layer. Floating gate memory devices store information by holding electrical charge within the floating gate. Adding or removing charge from the floating gate changes the threshold voltage of the cell, thereby defining whether the memory cell is in a “programmed” or “erased” state.

A SONOS device stores charge within discrete traps located in a nitride film in a gate dielectric. Therefore, the SONOS device is often referred to as a nitride-based read only memory (NROM).

The above-described types of memories are susceptible to environmental conditions, such as external radiation. Radiation can induce undesirable charge into the memory cell structure, resulting in a reduction in the sensitivity to the state of the stored memory bit. After radiation exposure, the write and erase state threshold voltages may begin to converge, which in turn will result in loss of the ability to distinguish between the write and erase state. The difference between the write and erase states is referred to as the memory window. As the threshold voltages of the two states converge, the memory window becomes smaller until there is no longer a memory window present and the ability to distinguish between the logic one (high V_{TH}) or zero (low V_{TH}) in the cell is lost.

### SUMMARY OF THE INVENTION

In one aspect, a radiation hardened transistor includes a buried source, buried drain and a poly-silicon gate separated from the buried source and the buried drain by a buried oxide. A recessed P+ implant or a blanket P+ implant is disposed in a substrate. A portion of the recessed P+ implant or a portion of the blanket P+ implant is disposed beneath outer edges of the poly-silicon gate, in a channel separating the buried source and the buried drain.

### BRIEF DESCRIPTION OF THE DRAWINGS

FIG. 1 is a diagrammatic representation of a SONOS NROM cell structure.

FIG. 2 illustrates the programming of a multi-bit SONOS NROM cell.

FIGS. 3A and 3B show cross sections of a single one transistor multi-bit SONOS NVSM device.

FIG. 4A shows a top view of a radiation hardened SONOS NVM cell in accordance with an embodiment.

FIG. 4B shows a transistor level schematic of a multi-bit SONOS array section.

FIG. 5 shows a cross-section of a radiation hardened SONOS NVM cell shown in FIG. 4A.

FIG. 6 shows a cross-section of a radiation hardened SONOS NVM cell shown in FIG. 4A.

FIGS. 7A and 7B show a method to manufacture a radiation hardened SONOS NVSM device in accordance with an embodiment.

FIG. 8 is a flowchart illustrating a refresh mechanism for memory cell exposed to radiation or other environmental conditions in accordance with an embodiment.

FIG. 9 is a flowchart illustrating an adaptive refresh operation in accordance with an embodiment.

### DETAILED DESCRIPTION

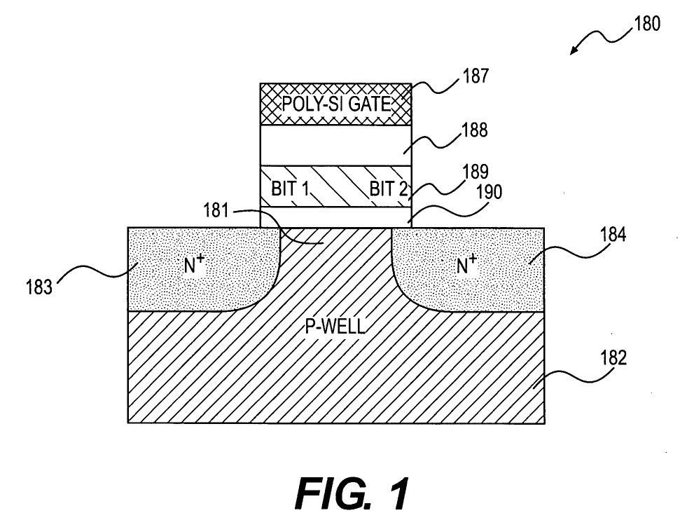

FIG. 1 is a diagrammatic representation of a SONOS NROM cell 180 structure. A NROM cell 180 contains a trapping nitride layer 189 (e.g., Si₃N₄), which stores charge instead of a floating gate suspended above the cell. The nitride layer 189 (e.g., approximately 40 Angstroms (Å) thick) is surrounded by two insulating oxide layers 188 and 190. The upper oxide layer 188 is referred to a blocking oxide layer (e.g., approximately 50 Å thick) and the lower oxide layer 190 is referred to as a tunnel oxide layer (e.g., approximately 50 Å thick). A poly-silicon gate 187, representing the word line (WL1) of the memory cell 180, is deposited over the blocking oxide 188. A channel region 181 formed in the P-type 182 substrate separates a first N+ region 183 from a second N+ region 184, as shown. In the NROM cell 180, the first N+ region 183 may represent a first bit line (BL1) and the second N+ region 184 may represent a second bit line (BL2). The first and second regions 183 and 184 represent source and drain regions of the NROM cell 180. The tunnel oxide 190, the nitride 189, the blocking oxide 188 and the poly-silicon gate 187 are located above the channel region 181 and portions of the source 183 and drain 184.

As indicated above, the NROM cell 180 comprises a nitride layer 189, which serves as a trapping dielectric for two separate localized charge packets at each end of the cell 180, effectively storing two bits. Each charge can be maintained in one of two states, either “programmed” or “erased,” represented by the presence or absence of a pocket of trapped electrons, which enables the storage of two bits of information. Each storage area in an NROM cell 180 can be programmed or erased independently of the other storage area. An NROM cell is programmed by applying a voltage that causes negatively charged electrons to be injected into the nitride layer near one end of the cell.

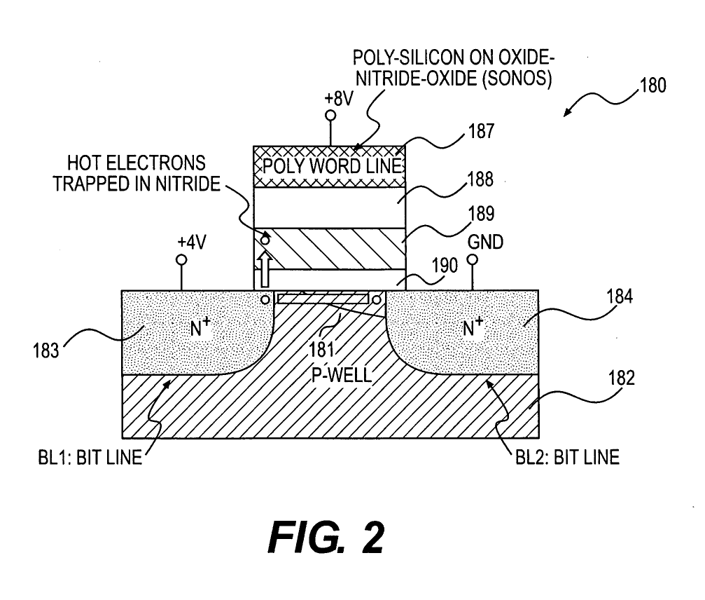

As shown in FIG. 2, programming of the left side of the multi-bit NROM cell 180 is accomplished by applying, for example, 4 Volts (V) to Bit Line 1 (BL1) 183 (drain), grounding Bit Line 2 (BL2) 184 (source) and applying a voltage (e.g., 8V) to the poly-silicon gate 187. As a result of the voltage differential between the source 184 and drain 183, electrons travel from source 184 (BL2) to drain 183 (BL1), across the channel 181, and are injected into the nitride layer 189 across the tunnel oxide 190 (as shown by the arrows). The electron charge 195 becomes trapped in the nitride layer 189 region closest to BL1 183. The stored or trapped charge 195 represents information stored in the memory cell.

To program the other side of the NMOS cell 180, BL1 183 is grounded and a voltage (e.g., 4V) is applied to BL2 184 (not shown). In this case, the electrons (e.g., charge 198) are trapped on the nitride layer 189 closest to BL2 184. Once the charge or electrons (e.g., charge 195 or 198) is stored, it can be read in a direction opposite to the direction it was programmed. The multi-bit functionality of the NROM cell 180 is achieved by storing charge (equivalent to one bit of data) at both sides (source and drain) of the device channel as evident from the symmetric nature of the structure.

Erasing of the NROM cell 180 is accomplished by applying voltages to a cell that cause positive charges, referred to as “holes” to be injected into the nitride layer and cancel the effect of the electrons previously stored there during programming. Because a significantly smaller amount of trapped charges is needed to program a device, and due to the physical mechanisms used for program and erase, the NROM cell 180 can be both programmed and erased faster than devices based on traditional floating gate technology. When the NROM cell 180 is programmed, the trapped electrons (negative charge) 195 create a positive shift in the threshold voltage of the NROM cell 180 due to the potential barrier created at the surface directly underneath the narrow charge storage region in the nitride layer 189. Due to the reverse read, the threshold voltage of the device is determined solely by the opposite (drain) bit. When the NROM cell 180 is erased, the holes either recombine with electrons or are trapped within the nitride, resulting in a negative shift in the threshold voltage of the memory device.

Due to the above indicated advantages of the SONOS or NROM devices, it is desirable to use these devices in radiation environments. However, ionizing radiation induces large amounts of trapped positive charge within thick oxide regions of the SONOS device. This trapped positive charge can significantly lower the NROM threshold voltage in p-type semiconductor channel regions immediately adjacent to the oxide edge (gate overlap region) and results in high off-state NMOS leakage currents (between the N+ doped source and drain regions).

The threshold voltages of SONOS devices are modulated by the presence of positive or negative charge within a charge storage layer. The low and high threshold voltage states are assigned logic values in order to store a bit of data in the memory cell. For example, the high threshold voltage is often referenced as a logic “one” while the low threshold voltage is referenced as the logic “zero.” Changes in the threshold voltage of the memory device directly correspond to whether (or not) a bit of information is stored within the memory cell. If the threshold voltage changes due to, for example, external radiation environments, the information stored in the SONOS NROM device may be misread or not read at all.

An embodiment provides a novel semiconductor device that may significantly increase the per unit area memory density of radiation hard non-volatile semiconductor memory (RHNVSM) by employing a multi-bit one transistor (1T) Silicon-Oxide-Nitride-Oxide-Silicon (SONOS) transistor structure. In an embodiment, a recessed P+ region or a blanket P+ region may be used to improve the radiation hardness of the SONOS non-volatile semiconductor memory (NVSM). In addition, radiation hardness of peripheral (e.g., to the memory array) NMOS transistors may also be improved using the structures or techniques described herein.

In an embodiment, one or more techniques are provided to periodically and/or adaptively refresh, for example, a SONOS memory cell or memory array to offset any detrimental effects of radiation exposure on the memory cell or memory array. For example, the memory cell may be adaptively refreshed after a pre-set radiation dose and may be refreshed several times in order to extend the life of the system. Additionally or optionally, the memory cell may be refreshed based on a predetermine time interval or based on a comparison between a present threshold value and a predetermined reference or target value. The stored memory bit may be refreshed using several different methods including a single re-write, erase then re-write, or an adaptive refresh. The refresh technique may provide an improvement in the ability of the system to disseminate between the write and erase states after elevated radiation doses.

A radiation-hard non-volatile memory relates to a NVM that is operated in ionizing radiation environments—such as outside of the earth's atmosphere—where the ionizing radiation induces positive trapped charge in thick oxide regions.

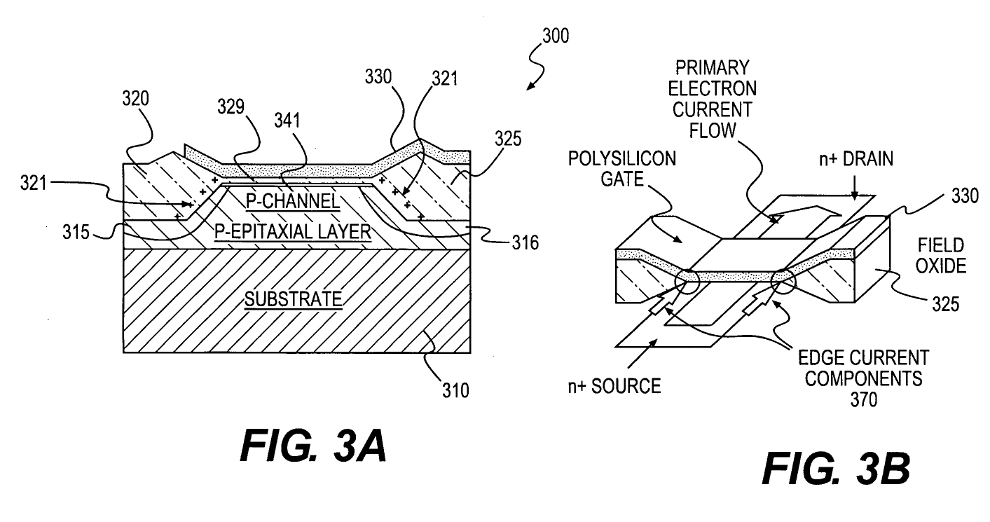

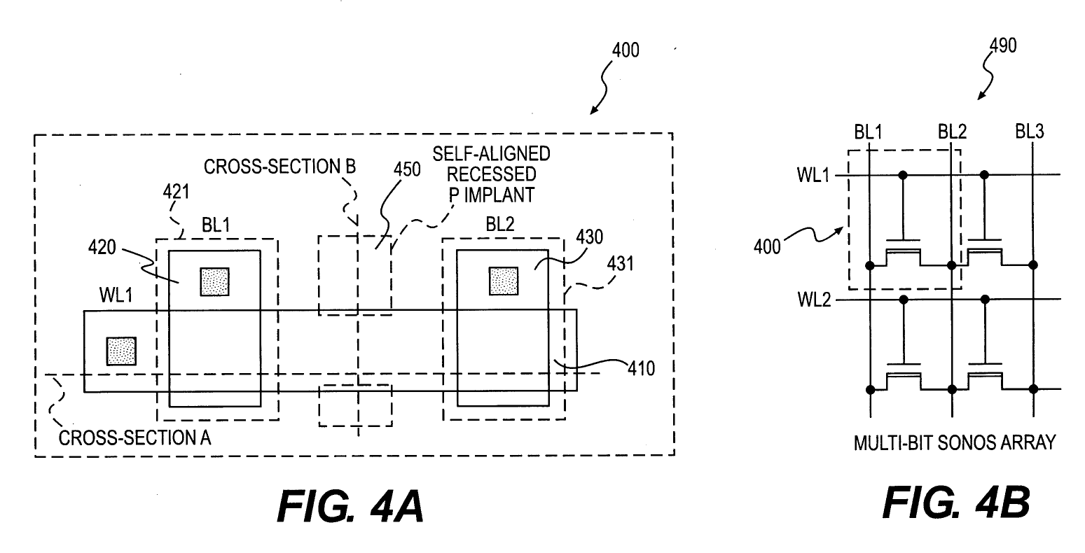

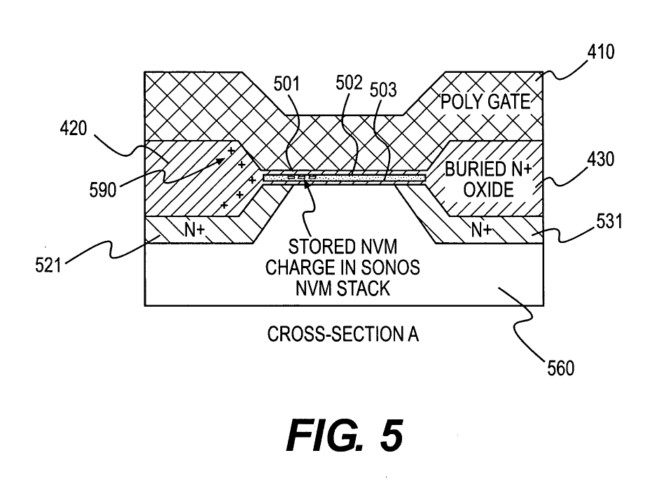

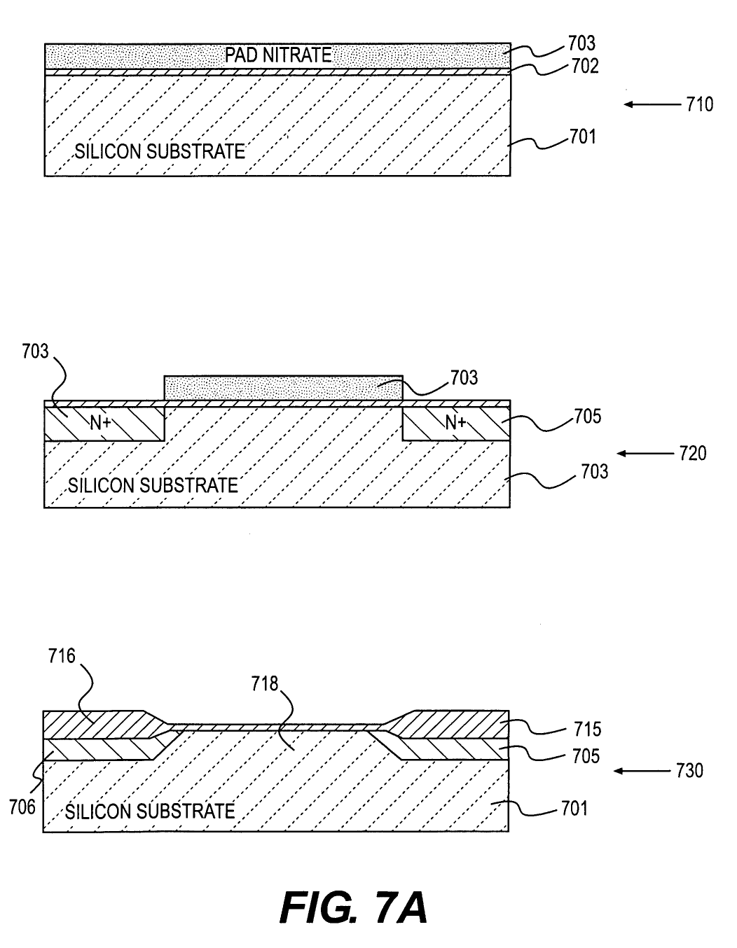

FIGS. 3A and 3B show cross sections of a single one transistor multi-bit SONOS NVSM device 300. The multi-bit SONOS device 300 is fabricated using a substrate 310, which may be a p-type substrate or n-type substrate. In a N-type SONOS device, a P-type channel 341 is positioned between N+ buried bit lines 315 and 316, which represent the source and drain of the transistor device 300. An oxide 320 and 325 is disposed on the N+ buried bit lines. A nitride charge layer 329 is deposited on a tunnel oxide (omitted), and a cap oxide (omitted) may be deposited on the charge layer 329. A poly-silicon gate 330 is deposited on portions of the oxide 320 and 325 and above the channel 341, as shown. If the multi-bit SONOS NVSM device 300 is exposed to radiation, then a positive charge 321 may be induced by the radiation and becomes trapped in the oxide 320 and 325, directly underneath the regions where the poly-silicon gate 330 overlaps the N+ source and drain edges. The trapped positive charge 321 is electrostatically shielded by buried bit lines 315 and 316 from the P-type channel 341 regions immediately adjacent to the oxide 320, 325 edge, which suppresses high off-state NMOS transistor radiation induced edge leakage currents 370 between the N+ doped source and drain regions, as shown in FIG. 3B of a NMOS transistor. The leakage edge currents 370 are induced by inversion of the P-type channel 341 edge region caused by the trapped positive charge 321 in field oxide 325. However, as illustrated in FIGS. 4A and 6, the NROM cell is still susceptible to radiation induced edge leakage currents, but in the direction perpendicular to the NMOS transistor of FIG. 3B.

SONOS type NVM have the ability to trap charge uniformly throughout the entire nitride, or locally within separate lateral regions of the nitride layer, which alters the threshold voltage in the channel directly below this stored charge. This allows independent regions of charge to store multiple bits of memory data within a single SONOS device, improving the density of stored memory bits.

FIG. 4A shows a top view of a radiation hardened SONOS NVM cell 400, in accordance with an embodiment. The radiation hardened cell 400 includes a poly-silicon word line 410 (WL1), a buried N+ oxide 420 and a buried N+ oxide 430. The radiation hardened cell 400 also includes first bit-line (BL1) 421 and second bit line (BL2) 431. The radiation hardened cell 400 also includes recessed P+ implant 450 positioned between the buried N+ oxide regions 420, 430 to break a leakage current path and prevent the reduction of the device threshold voltage, as described below. As shown, the P+ implant 450 are deposited at the outer edges of the poly-silicon gate 410.

FIG. 4B shows a transistor level schematic of a multi-bit SONOS array section 490. The dotted line represents the radiation hardened SONOS NVM cell 400 shown in FIG. 4A. The SONOS array section 490 shows a word line (e.g., WL1), and bit lines (e.g., BL1 and BL2).

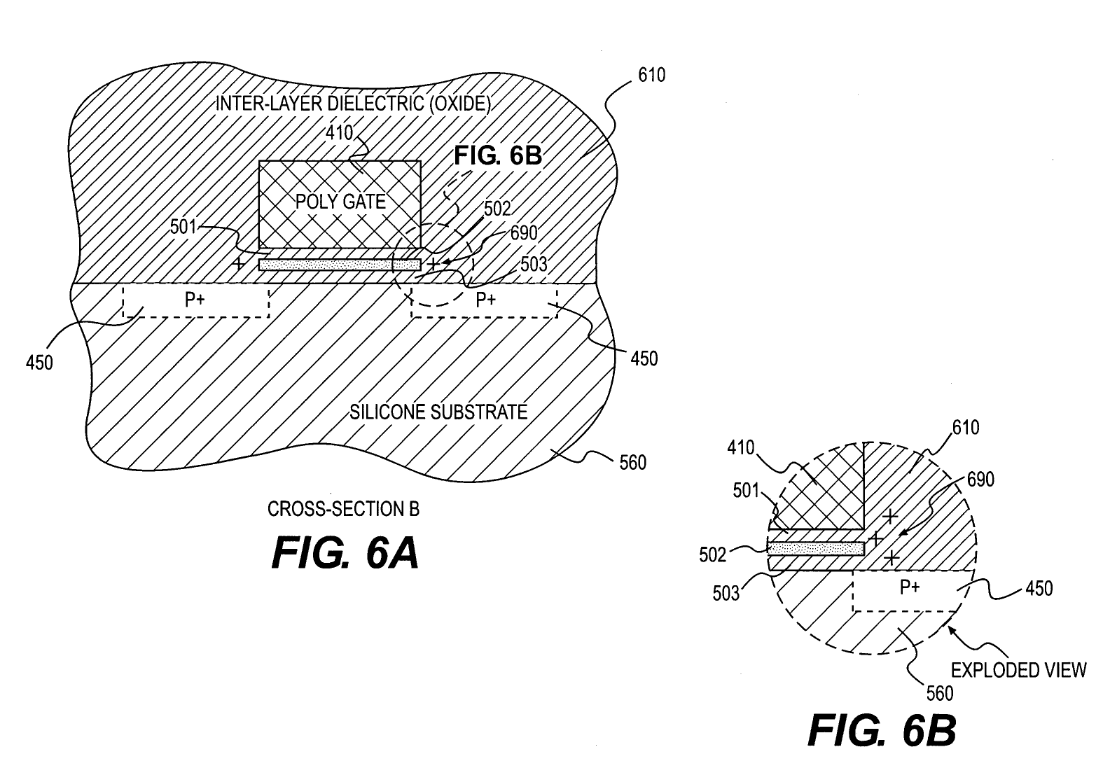

FIG. 5 shows “Cross-Section A” of radiation hardened SONOS NVM cell 400, shown in FIG. 4A. FIG. 5 shows a cross-section of a portion of the SONOS NVM cell, which includes a substrate 560 that may be a P-type substrate or N-type substrate. Buried N+ bit lines 521 and 531 are deposited between buried N+ oxide 420, 430, respectively, and substrate 560. The cross-section also shows a trapping nitride layer 502, which stores charge. The trapping nitride layer 502 is surrounded by two insulating oxide layers 501 and 503. The upper oxide layer 501 is referred to as a blocking oxide layer and the lower oxide layer 503 is referred to as a tunnel oxide layer. A poly-silicon gate 410 is deposited over the buried N+ oxide 420, 430 and the upper oxide layer 501.

FIG. 6 shows “Cross-Section B” of radiation hardened SONOS NVM cell 400, shown in FIG. 4A. Cross-section B shows portions of self-aligned recessed P+ implant 450 disposed beneath outer edges of the poly-silicon gate 410, as shown in FIG. 6. FIG. 6 also shows an exploded view of the P+ implant portion 450. As shown in FIGS. 5 and 6, and as described herein, trapped radiation induced charge 590 and 690 can build up adjacent to the edge or side of the poly silicon gate sidewalls and may result in a lower threshold voltage for the device and induce channel leakage current between the buried bit line source and drain. In accordance with an embodiment, the self-aligned recessed P+ implant 450 increases the threshold voltage in the silicon substrate region directly beneath the poly gate edge, suppressing the channel leakage current induced by radiation induced positive charge.

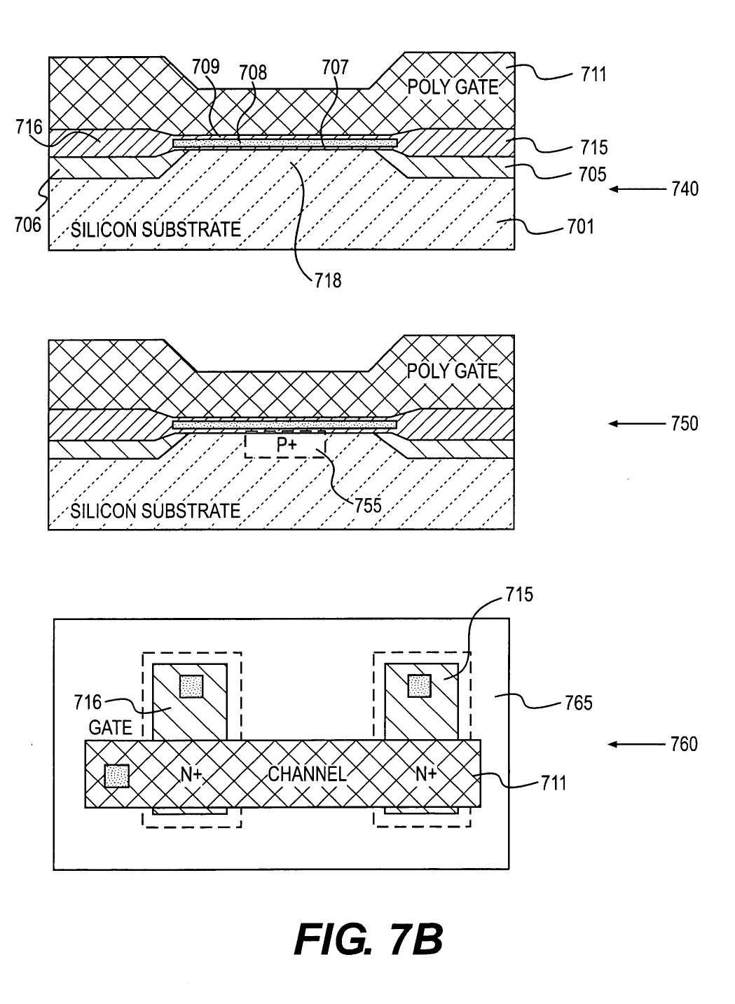

FIGS. 7A and 7B show a method to manufacture a radiation hardened SONOS NVSM device, in accordance with an embodiment. As shown in step 710, pad oxide layer 702 is deposited on silicon substrate 701. A pad nitride layer 703 is deposited on the pad oxide layer 702. As shown in step 720, the nitride layer 703 is etched and N+ bit lines 705 and 706 are implanted. Insulating oxide regions 715 and 716 are grown above the N+ bit lines 705 and 706, respectively, as shown in step 730. The nitride layer 703 over the substrate channel region 718 is stripped.

As shown in step 740 of FIG. 7B, the pad oxide layer 702 is stripped and a tunnel oxide layer 707 (e.g., approximately 50 Å thick) 707 is grown over the substrate channel region 718. A nitride charge storage layer 708 is deposited on the tunnel oxide layer 707, and a cap oxide layer 709 is deposited on the nitride charge storage layer 708, as shown. A poly silicon gate layer 711 is deposited over the insulating oxide regions 715 and 716, and the cap oxide layer 709. The poly silicon gate layer 711 (i.e., the word line) is patterned and etched, as shown in step 750. Recessed self-aligned P+ regions 710 are patterned and implanted. Diffusion and rapid thermal annealing steps are used to drive or diffuse portions of the P+ regions 755 underneath the poly silicon gate 711 outer edges.

In an alternative embodiment, as shown in step 760, a blanket P-type implant 765 may be diffused instead of the self-aligned P+ regions 755. The blanket P-type implant 765 raises the NMOS threshold voltage in all P-type regions that enclose the poly silicon gate and the buried N+ regions. Using the blanket P-type implant, the memory cell size may be reduced since the buried bit lines (e.g., bit lines 521 and 531) can be formed closer to each other since the recessed self-aligned P+ regions are not required.

Techniques described above may eliminate the threshold voltage shift resulting from radiation-induced charge trapping in the buried oxide as well as edge leakage. However, charge trapping in the NROM gate dielectric layer may also degrade memory operation. Radiation-induced positive charge introduced to the NROM gate dielectric can either trap within the dielectric layer or recombine with electrons stored in the nitride layer (in the write state). Both conditions can result in a shift of the threshold voltage (V_{TH}) toward the depletion mode and an overall reduction in the sensitivity to the state of the stored memory bit. Consequently, the write and erase state threshold voltages begin to converge after radiation exposure, which in turn will result in loss of the ability to distinguish between the write and erase state. The difference between the write and erase states is referred to as the memory window. As the threshold voltages of the two states converge, the memory window becomes smaller until there is no longer a memory window present and the system cannot distinguish between the logic one (high V_{TH}) or zero (low V_{TH}) and the data is lost.

To mitigate effects of radiation-induced charge trapping in the gate dielectric, one or more methods are provided for incrementally refreshing the memory state during radiation exposure, enhancing radiation hardened memory performance. In an embodiment, the stored memory state is refreshed after a memory device or cell has been exposed to a pre-set or incremental level of radiation as illustrated. The refresh techniques described herein provide a dramatic improvement in the ability of the system to disseminate between the write and erase states after elevated radiation doses.

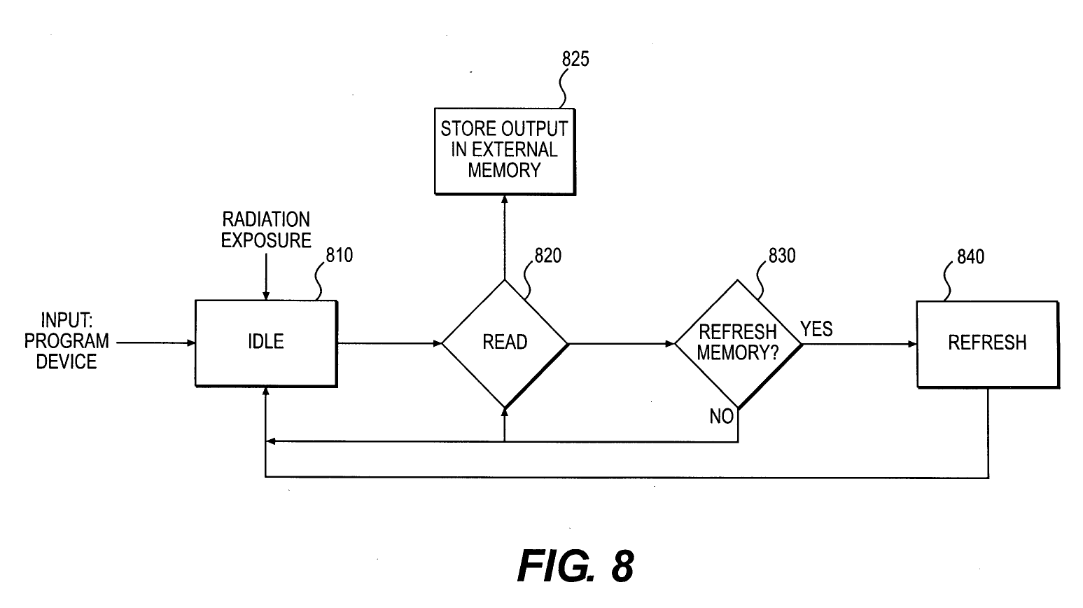

FIG. 8 is a flowchart illustrating a refresh mechanism for memory cell exposed to radiation or other environmental conditions in accordance with an embodiment. Radiation or other environmental exposure may change the characteristics of the memory cell. After the memory device such as a NROM device are programmed with data, they are placed in the idle mode to retain the programmed data. During data retention in the idle mode, incident radiation may hit the device, as shown in box 810. As described above, the incident radiation may alter the stored memory state. As shown in box 820, the device is triggered from the idle mode into the read mode by the system after a specified radiation dose is detected. The memory state threshold voltage is read and may be temporarily stored in an external memory, as shown in box 825. Based on the memory state voltage, it is determined whether the memory needs to be refreshed, as shown in box 830. The memory state threshold voltage may be compared to a reference cell voltage to determine if the threshold voltage has drifted toward the depletion mode and if so, the refresh of the memory state is triggered, as shown in box 840. In an embodiment, the memory state may be refreshed as many times as required or appropriate.

Referring again to FIG. 8, at box 830, if the memory does not need to be refreshed, then the process may return to steps 810 or 820.

The memory state refresh may be handled using different methods. For example, the memory state can be refreshed simply by injecting additional electrons into the memory device to compensate for electrons which have recombined with the radiation-induced charge. This technique may be referred to as a “rewrite,” which results in a larger memory window.

A second approach for refreshing the write state is to first erase the memory device and then re-write the device. This approach prevents excess of electrons from being injected into the memory bit so the device is not over-written.

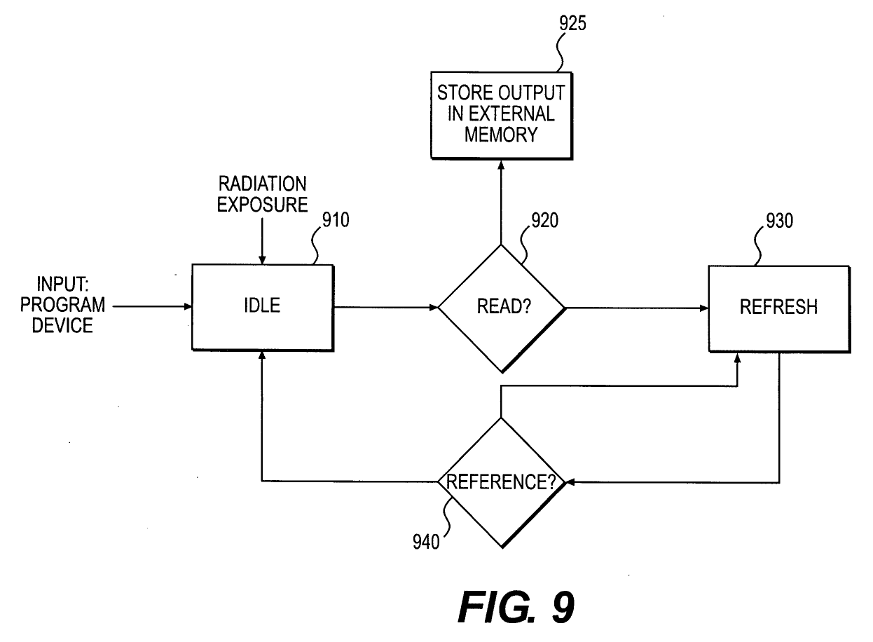

FIG. 9 is a flowchart illustrating an adaptive refresh operation in accordance with an embodiment. Using the adaptive refresh technique, the memory cell may be programmed with either reduced voltages or for a shorter period of time in order to produce a smaller and more controlled shift in the threshold voltage. As shown in boxes 910, during data retention in the idle mode, incident radiation may hit the device. The device is triggered from the idle mode into the read mode after a specified radiation dose is detected, as shown in box 920. As shown in box 925, the memory state threshold voltage is read and may be temporarily stored in an external memory. The memory state threshold voltage is compared to the reference cell voltage and can be repeatedly refreshed until the desired threshold voltage is achieved, as shown in boxes 930-940. This technique may be employed to refresh both the write and erase states. It is desirable to keep the erase state in an enhancement mode in order to ensure proper operation in a NAND-style array.

Several embodiments of the present invention are specifically illustrated and/or described herein. However, it will be appreciated that modifications and variations of the present invention are covered by the above teachings and within the purview of the appended claims without departing from the spirit and intended scope of the invention.

What is claimed is:

1. A radiation hardened transistor comprising:
a buried source;
a buried drain;
a poly-silicon gate separated from the buried source and the buried drain by a buried oxide; and
a recessed P+ implant or a blanket P+ implant disposed in a substrate, wherein a portion of the recessed P+ implant or a portion of the blanket P+ implant is disposed beneath outer edges of the poly-silicon gate, in a channel separating the buried source and the buried drain.

2. The radiation hardened transistor of claim 1, wherein the radiation hardened transistor comprises a single transistor multi-bit non-volatile memory.

3. The radiation hardened transistor of claim 2, wherein the buried source comprises a first bit line of the single transistor multi-bit non-volatile memory and the buried drain comprises a second bit line of the single transistor multi-bit non-volatile memory.

4. The radiation hardened transistor of claim 2, wherein the poly-silicon gate comprises a word line of the single transistor multi-bit non-volatile memory.

5. The radiation hardened transistor of claim 1, wherein the portion of the recessed P+ implant or the portion of the blanket P+ implant is diffused in the channel directly beneath the outer edges of the gate separating the buried source and the buried drain.

6. The radiation hardened transistor of claim 1, wherein the blanket P+ implant is disposed over portions of the poly-silicon gate and the buried oxide.

7. The radiation hardened transistor of claim 6, wherein the recessed P+ implant or the blanket P+ implant raises an edge threshold voltage in outer edges of the channel directly beneath the poly-silicon gate.

8. The radiation hardened transistor of claim 1, wherein the recessed P+ implant or the blanket P+ implant suppresses a channel leakage current produced by radiation induced positive charge.

9. The radiation hardened transistor of claim 1, wherein the buried source comprises a first buried N+ bit line and the buried drain comprises a second buried N+ bit line.

10. The radiation hardened transistor of claim 1, further comprising:
a charge storage nitride layer disposed under the poly-silicon gate, wherein the charge storage nitride layer separates the poly-silicon gate from the portion of the recessed P+ implant or from the portion of the blanket P+ implant disposed beneath outer edges of the poly-silicon gate in the channel.

11. The radiation hardened transistor of claim 10, further comprising:
a tunnel oxide layer disposed under the charge storage nitride layer, wherein the tunnel oxide layer is disposed between the charge storage nitride layer and the substrate, and wherein the tunnel oxide layer permits charge to flow from the substrate to the charge storage nitride layer.

12. The radiation hardened transistor of claim 10, further comprising:
a cap oxide layer disposed over the charge storage nitride layer, wherein the cap oxide layer is disposed between the charge storage nitride layer and the poly-silicon gate.

13. The radiation hardened transistor of claim 1, wherein the substrate comprises a P-type substrate.

14. The radiation hardened transistor of claim 13, wherein the radiation hardened transistor comprises a N-type Silicon-Oxide-Nitride-Oxide-Silicon (NSONOS) structure.

15. A method for fabricating a radiation hardened transistor, the method comprising:
depositing an oxide layer on a silicon substrate;
depositing a charge storage nitride layer on the oxide layer;
etching a portion of the charge storage nitride layer;
implanting first and second N+ bit lines in the silicon substrate;
growing an oxide region above the first and second N+ bit lines;
depositing a nitride charge storage layer above a channel disposed between the first and second N+ bit lines;
forming a poly-silicon gate above the oxide region and the nitride charge storage layer; and
diffusing a recessed P+ implant or a blanket P+ implant in the silicon substrate in a channel separating the first and second N+ bit lines, wherein a portion of the recessed P+ implant or a portion of the blanket P+ implant is diffused under edge portions of the poly-silicon gate.

16. The method of claim 15, further comprising:
depositing the blanket P+ implant over portions of the poly-silicon gate and the oxide.

17. The method of claim 15, wherein the recessed P+ implant or the blanket P+ implant suppresses a channel leakage current produced by radiation induced positive charge.

18. The method of claim 15, wherein the recessed P+ implant is diffused before the poly-silicon gate is formed.

19. The method of claim 15, wherein the recessed P+ implant is diffused after the poly-silicon gate is formed.

20. The method of claim 15, further comprising:
growing a tunnel oxide layer above the silicon substrate and under the nitride charge storage layer.

21. The method of claim 15, further comprising:
depositing a cap oxide layer under the poly-silicon gate and above the nitride charge storage layer.

22. The method of claim 15, wherein the silicon substrate comprises a P-type substrate.

23. The method of claim 15, wherein the radiation hardened transistor comprises a N-type Silicon-Oxide-Nitride-Oxide-Silicon (NSONOS) structure.

24. A method for fabricating a radiation hardened transistor, the method comprising:
depositing an oxide layer on a silicon substrate;
diffusing a recessed P+ implant or a blanket P+ implant in the silicon substrate in a channel separating a first and second N+ bit lines, wherein a portion of the recessed P+ implant or a portion of the blanket P+ implant is diffused under edge portions of a poly-silicon gate.

25. The method of claim 24, further comprising:
depositing the blanket P+ implant over portions of the poly-silicon gate and the oxide.

26. The method of claim 24, wherein the recessed P+ implant or the blanket P+ implant suppresses a channel leakage current produced by radiation induced positive charge.

27. The method of claim 24, wherein the recessed P+ implant is diffused before the poly-silicon gate is formed.

28. The method of claim 24, wherein the recessed P+ implant is diffused after the poly-silicon gate is formed.

29. The method of claim 24, wherein the silicon substrate comprises a P-type substrate.

30. The method of claim 24, wherein the radiation hardened transistor comprises a N-type Silicon-Oxide-Nitride-Oxide-Silicon (NSONOS) structure.

31. A method for preventing a threshold voltage shift in a multi-bit N-type Silicon-Oxide-Nitride-Oxide-Silicon (NSONOS) device exposed to radiation, the method comprising:
reading contents of a NSONOS cell to external circuitry;
determining a present state threshold voltage associated with contents of the NSONOS cell;
comparing the present state threshold voltage with a predetermined reference threshold voltage;
if, based on the comparison, the present state threshold voltage drifts from the predetermined reference threshold voltage, triggering a memory refresh of the NSONOS cell, wherein the memory refresh resets the present threshold voltage of the NSONOS cell to a predetermined target voltage.

32. The method of claim 31, wherein the predetermined reference threshold voltage is equal to the predetermined threshold voltage.

33. The method of claim 31, wherein the NSONOS device comprises a radiation hardened NSONOS device.

34. The method of claim 31, further comprising:
triggering the NSONOS cell from an idle mode to a read mode if a specified radiation dose is detected.

35. The method of claim 31, further comprising:
storing the present state threshold voltage in an external memory during the comparing.

36. A method for preventing a threshold voltage shift in a multi-bit N-type Silicon-Oxide-Nitride-Oxide-Silicon (NSONOS) device exposed to radiation, the method comprising:
periodically triggering a memory refresh of a NSONOS cell of the NSONOS device, wherein the memory refresh resets a present threshold voltage of the NSONOS cell to a predetermined target voltage.

37. The method of claim 36, further comprising:
determining a period for periodically triggering the memory refresh, wherein the period is time dependent.

38. The method of claim 36, further comprising:
determining a period for periodically triggering the memory refresh, wherein the period is based on a predetermined dose of radiation exposure by the NSONOS device.

39. The method of claim 36, further comprising:
determining a period for periodically triggering the memory refresh, wherein the period is based on a comparison between a present state threshold voltage associated with the NSONOS cell and a predetermined reference threshold voltage.

40. The method of claim 36, further comprising:
repeating the periodic triggering to refresh the NSONOS cell until a desired threshold voltage is reached.
